(19) United States
(12) Patent Application Publication
(10) Pub. No.: US 2026/0005061 A1
(43) Pub. Date: Jan. 1, 2026

(54) WAFER CHUCKING SYSTEM

(71) Applicant: SAMSUNG ELECTRONICS CO., LTD., Suwon-si (KR)

(72) Inventors: Sunghyup KIM, Suwon-si (KR); Hyojin KOOK, Suwon-si (KR); Mijeong SHIN, Suwon-si (KR); Sebin CHOI, Suwon-si (KR)

(21) Appl. No.: 18/971,875

(22) Filed: Dec. 6, 2024

(30) Foreign Application Priority Data
Jun. 28, 2024 (KR) 10-2024-0085356

(51) Int. Cl. H01L 21/683

(52) U.S. Cl. CPC H01L 21/6838

(57) ABSTRACT

A wafer chucking system includes a membrane structure including a first layer having a first coefficient of thermal expansion (CTE) on which a wafer is mountable, and a second layer having a second CTE different from the first CTE, a temperature controller configured to thermally deform the membrane structure by heating or cooling the membrane structure, and an adsorber configured to adsorb the wafer on the membrane structure.

### CROSS-REFERENCE TO RELATED APPLICATION

This application claims the benefit of Korean Patent Application No. 10-2024-0085356 filed on June 28, 2024, in the Korean Intellectual Property Office, the entire disclosure of which is incorporated herein by reference in its entirety.

### BACKGROUND

### 1. Field of the Invention

One or more embodiments relate to a wafer chucking system.

### 2. Description of the Related Art

There may be an issue of warpage arising due to thermal and/or mechanical stress in processes of manufacturing semiconductor dies or packages. Such a semiconductor warpage may significantly impact the reliability and performance of semiconductor products. The semiconductor warpage may also lead to mechanical failures including, for example, cracking and delamination, and the degradation of device characteristics. Additionally, the semiconductor warpage that exceeds an equipment tolerance may hinder the progress of the processes. The above description is information the inventor(s) acquired during the course of conceiving the present disclosure, or already possessed at the time, and is not necessarily art publicly known before the present application was filed.

### SUMMARY

According to an aspect, a wafer chucking system includes a membrane structure having a first layer with a first coefficient of thermal expansion (CTE) on which a wafer is mountable, and a second layer with a second CTE different from the first CTE. A temperature controller is configured to heat or cool the membrane structure to thermally deform the membrane structure, and an adsorber is configured to adsorb the wafer on the membrane structure.

In some embodiments, the adsorber may include an adsorption electrode on a lower side of the membrane structure that is configured to accumulate a charge when a voltage is applied thereto by a power supply. The power supply is configured to control a magnitude of the voltage applied to the adsorption electrode.

In some embodiments, the first layer and the second layer may each include at least one first aperture and at least one second aperture that are in fluid communication with each other. The adsorber may include a vacuum line in fluid communication with the at least one first aperture and the at least one second aperture. The vacuum line is configured to provide a negative pressure to the wafer. A vacuum pump is configured to adjust a vacuum level in the vacuum line.

In some embodiments, the wafer chucking system may further include a rigid base, and an elastic body between the membrane structure and the rigid base. The elastic body may stretch and shrink in response to a change in a height of each region of the membrane structure relative to the base.

In some embodiments, the elastic body may be formed of a material having a thermal conductivity lower than an average thermal conductivity of the membrane structure.

In some embodiments, the elastic body may be formed of a porous, elastic medium.

In some embodiments, the wafer chucking system may further include at least one sliding guide on the base, and at least one floating rod on the second layer that is configured to slide along the at least one sliding guide in response to deformation of the membrane structure.

In some embodiments, the at least one sliding guide includes a plurality of sliding guides, and the at least one floating rod includes a plurality of floating rods. The plurality of floating rods are in contact with the second layer, and the plurality of sliding guides are in contact with the rigid base.

In some embodiments, the at least one floating rod may have a diameter greater than a diameter of the at least one sliding guide and includes an internal space that receives the at least one sliding guide therein. In some embodiments, the at least one elastic body surrounds a periphery of the at least one sliding guide. The at least one elastic body includes opposite ends that are supported by the floating rod and the base, respectively.

In some embodiments, the temperature controller may include a heat conductor in the at least one sliding guide. The heat conductor may be configured to heat or cool the second layer through the at least one sliding guide and the at least one floating rod.

In some embodiments, the temperature controller may include a heat conductor directly connected to the at least one floating rod or the second layer through the at least one sliding guide.

In some embodiments, the at least one sliding guide may have a diameter greater than a diameter of the at least one floating rod and includes an internal space that receives the at least one floating rod therein. In some embodiments, the at least one elastic body surrounds a periphery of the at least one floating rod. The at least one elastic body includes opposite ends that are supported by the second layer and the at least one sliding guide, respectively.

In some embodiments, the membrane structure may have a plurality of regions and the temperature controller may include a plurality of heat conductors each configured to independently heat or cool a respective one of the plurality of regions.

In some embodiments, the membrane structure may have a plurality of regions and may further include insulating material between the plurality of regions that is configured to reduce an amount of heat conducted between the plurality of regions.

In some embodiments, the plurality of regions may be arranged in an angular direction around a point of the membrane structure.

In some embodiments, at least a portion of the plurality of regions may include a plurality of sub-regions radially sectioned from the one point of the membrane structure.

In some embodiments, the plurality of regions may be arranged radially from one point of the membrane structure.

In some embodiments, at least a portion of the plurality of regions may include a plurality of sub-regions sectioned in an angular direction around the one point of the membrane structure.

In some embodiments, the plurality of regions may be arranged parallel to each other on the membrane structure.

According to another aspect, a wafer chucking system includes a membrane structure having a plurality of layers, each of the plurality of layers having a respective different CTE. A temperature controller is configured to heat or cool the membrane structure to thermally deform the membrane structure, and an adsorber is configured to adsorb the wafer on the membrane structure.

A CTE of a layer on an upper side of a first region among the plurality of regions may have a higher value than a CTE of a layer on a lower side of the first region. A CTE of a layer on an upper side of a second region adjacent to the first region among the plurality of regions may have a lower value than a CTE of a layer on a lower side of the second region.

A difference in CTEs of two layers respectively on upper and lower sides of the first region among the plurality of regions may have a different value from a difference in CTEs of two layers respectively on upper and lower sides of a second region adjacent to the first region among the plurality of regions.

According to other aspects, a wafer chucking system includes a membrane structure having a first layer with a first coefficient of thermal expansion (CTE) on which a wafer is mountable, and a second layer with a second CTE that is different from the first CTE. The wafer chucking system also includes a rigid base, a plurality of sliding guides attached to one of the base and the second layer, and a plurality of floating rods attached to the other one of the base and the second layer. Each of the plurality of floating rods are configured to slide along a respective one of the plurality of sliding guides in response to deformation of the membrane structure. The wafer chucking system also includes a plurality of elastic bodies. Each elastic body extends around a periphery of a respective one of the plurality of sliding guides and each of the plurality of elastic bodies are configured to expand and contract in response to a change in a height of a respective region of the membrane structure relative to the base. A temperature controller is configured to heat or cool the membrane structure to thermally deform the membrane structure, and an adsorber is configured to adsorb the wafer on the membrane structure.

Additional aspects of embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a diagram illustrating a wafer chucking system according to an embodiment;

FIG. 2 is a block diagram illustrating a wafer chucking system according to an embodiment;

FIGS. 3A to 3C are diagrams illustrating various warpage shapes of a wafer;

FIG. 4 is a conceptual diagram illustrating a deformation principle of a membrane structure according to an embodiment;

FIG. 5 is a diagram illustrating a membrane structure deformed to have a smile warpage shape by using a wafer chucking system according to an embodiment;

FIG. 6 is a diagram illustrating a membrane structure deformed to have a crying warpage shape by using a wafer chucking system according to an embodiment;

FIG. 7 is a diagram illustrating a wafer chucking system according to an embodiment;

FIG. 8 is a perspective view of a wafer chucking system according to an embodiment;

FIG. 9 is an enlarged view of section A of FIG. 8;

FIG. 10 is a side view of a wafer chucking system according to an embodiment;

FIG. 11 is a cross-sectional view according to an embodiment of section B of FIG. 10;

FIG. 12 is a diagram illustrating a membrane structure deformed to have a smile warpage shape by using a wafer chucking system according to an embodiment;

FIG. 13 is a diagram illustrating a membrane structure deformed to have a crying warpage shape by using a wafer chucking system according to an embodiment;

FIG. 14 is a diagram illustrating a membrane structure deformed to have a wave warpage shape by using a wafer chucking system according to an embodiment;

FIG. 15 is a cross-sectional view according to an embodiment of section B of FIG. 10;

FIG. 16 is a cross-sectional view according to an embodiment of section B of FIG. 10;

FIG. 17 is a diagram illustrating a method of controlling a temperature for each region of a membrane structure according to an embodiment;

FIG. 18 is a diagram illustrating a method of controlling a temperature for each region of a membrane structure according to an embodiment;

FIG. 19 is a diagram illustrating a method of controlling a temperature for each region of a membrane structure according to an embodiment;

FIG. 20 is a perspective view illustrating a membrane structure according to an embodiment;

FIG. 21 is a top view of a membrane structure according to an embodiment;

FIG. 22 is a side view illustrating a membrane structure and a deformed membrane structure according to an embodiment; and

FIG. 23 is a side view of a wafer chucking system according to an embodiment.

### DETAILED DESCRIPTION

Hereinafter, embodiments will be described in detail with reference to the accompanying drawings. However, various alterations and modifications may be made to the embodiments and thus, the scope of the disclosure is not limited or restricted to the embodiments. The equivalents should be understood to include all changes, equivalents, and replacements within the idea and the technical scope of the disclosure.

The terminology used herein is for the purpose of describing particular embodiments only and is not to be limiting of the embodiments. The singular forms "a," "an," and "the" are intended to include the plural forms as well, unless the context clearly indicates otherwise. It will be further understood that the terms "comprises/comprising" and/or "includes/including" when used herein, specify the presence of stated features, integers, steps, operations, elements, and/or components, but do not preclude the presence or addition of one or more other features, integers, steps, operations, elements, components and/or groups thereof.

As used herein, "A or B", "at least one of A and B", "at least one of A or B", "A, B or C", "at least one of A, B and C", and "at least one of A, B, or C," may include any one of the items listed together in the corresponding one of the phrases, or all possible combinations thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, the terms first, second, A, B, (a), and (b) may be used to describe constituent elements of the embodiments. These terms are used only for the purpose of discriminating one component from another component, and the nature, the sequences, or the orders of the components are not limited by the terms. It should be noted that if it is described that one component is "connected", "coupled", or "joined" to another component, a third component may be "connected", "coupled", and "joined" between the first and second components, although the first component may be directly connected, coupled, or joined to the second component.

A component, which has the same common function as a component included in any one embodiment, will be described by using the same name in other embodiments. Unless disclosed to the contrary, the description of any one embodiment may be applied to other embodiments, and the specific description of the repeated configuration will be omitted.

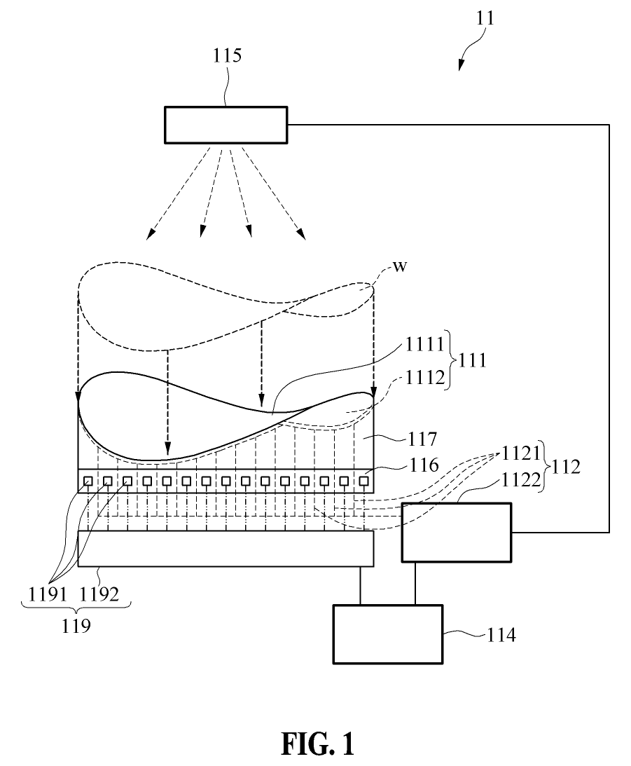

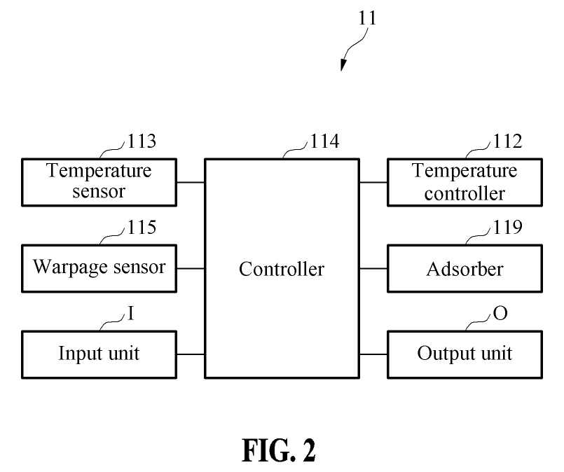

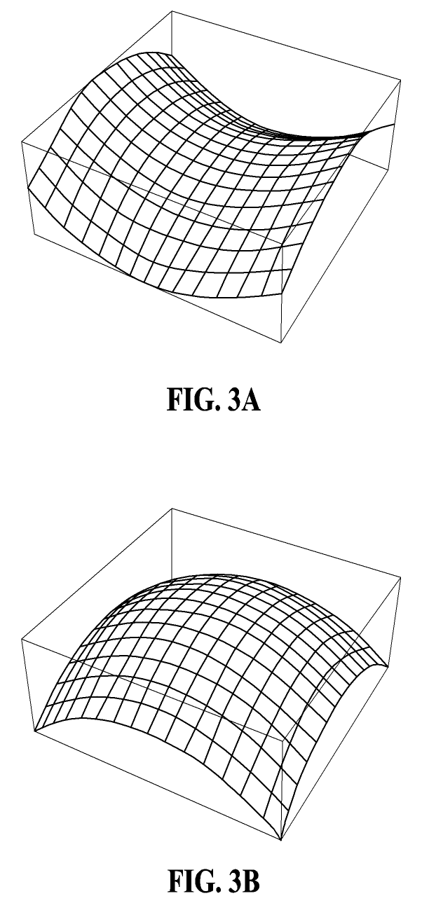

FIG. 1 is a diagram illustrating a wafer chucking system according to an embodiment, FIG. 2 is a block diagram illustrating a wafer chucking system according to an embodiment, and FIGS. 3A to 3C are diagrams illustrating various warpage shapes of a wafer.

Referring to FIGS. 1 to 3C, layers of various materials are deposited during a semiconductor manufacturing process on a surface of a wafer w, and the wafer w is repeatedly subjected to a high-temperature process. At this time, thermal stress is generated due to a difference in a coefficient of thermal expansion (CTE) between the materials forming the layers, and the wafer w is bent in a specific direction, which is called warpage. For example, warpage may occur in a deposition process and an etching process in which materials with different CTEs are deposited or removed. In addition, in a process of applying a heated photoresist (PR) in a photolithography process or in an annealing process of heating the wafer w, warpage may occur as a temperature of the wafer w changes. Examples of warpage include saddle-shaped warpage shown in FIG. 3A, crying-shaped warpage (i.e., when viewed edge on, the left and right edges of the wafer w are downwardly extending so that the wafer w is convex in an upward direction) shown in FIG. 3B, and smile-shaped warpage (i.e., when viewed edge on, the left and right edges of the wafer w are upwardly extending so that the wafer w is concave in an upward direction) shown in FIG. 3C.

The saddle-shaped warpage is generated in large quantities during the process of producing high-layer flash products such as V-NAND. In V-NAND products, a bonding process of connecting a cell and a peri is essential, however, saddle-shaped warpage may occur due to a difference in stress between cells during the bonding process. Various shapes of warpage including such a saddle-shaped warpage may cause problems during a chucking process of fixing the wafer w to a wafer chuck. The bent wafer w does not completely come into contact with a flat wafer chuck. Due to this, a position of the wafer w may be unintentionally shaken during a semiconductor manufacturing process, which may cause defects of a product. In addition, when the wafer w is bent, it is difficult to accurately specify positions of semiconductor devices on the wafer w. Therefore, it may be a big problem in the lithography process that requires precision during the semiconductor manufacturing process, which may negatively affect the performance of a semiconductor circuit. In addition, when the wafer w is forced to be chucked to a wafer chuck, a problem of cracking the wafer w may occur. That is, when the wafer w is not properly fixed to the wafer chuck, errors occur in the semiconductor manufacturing process, which ultimately reduces a yield of semiconductor chips. In addition, this requires additional inspection and maintenance processes, which increases manufacturing costs.

When there is warpage on the wafer w as described above, a wafer chucking system 11 according to an embodiment may thermally deform a membrane structure 111 that functions as an upper end portion of a wafer chuck according to a warpage shape of the wafer w. For example, the membrane structure 111 may be deformed so that the wafer w having saddle-shaped warpage, as shown in FIG. 1, may be stably placed (i.e., the membrane structure 111 deforms into the identical saddle shape of the wafer w such that bottom surface of the wafer w is entirely or substantially entirely in contact with the membrane structure 111 when adsorbed thereto). The term “stably placed” means that the membrane structure 111 is deformed into the identical shape of any wafer w (i.e., a wafer w with “smile-shaped” warpage, a wafer w with “crying-shaped” warpage, a wafer w with “saddle-shaped” warpage, a wafer w with any other type of warpage, etc.) such that bottom surface of the wafer w is entirely or substantially entirely in contact with the membrane structure 111 when adsorbed thereto. Through this, the wafer w having the warpage may also be properly fixed onto the membrane structure 111. Therefore, damage to the wafer w may be prevented, and the wafer w may be stably chucked on the wafer chuck, thereby improving the efficiency of the semiconductor manufacturing process and reducing the manufacturing cost. In addition, when the wafer chucking system 11 is applied to semiconductor process equipment that involves an environment where a temperature changes, the membrane structure 111 may be deformed according to the warpage shape of the wafer w according to a product or a process stage to chuck the wafer w. Therefore, it is possible to actively respond to various deformations that appear in the warpage of the wafer w. For example, the wafer chucking system 11 may be applied to (i) thermal oxidation process equipment for forming an oxide film, (ii) lithography process equipment having spin coating, exposure, and development, (iii) thin film deposition process equipment, and/or (iv) dry or wet etching process equipment. For example, the wafer chucking system 11 may include the membrane structure 111, a temperature controller 112, a temperature sensor 113, a controller 114, a warpage sensor 115, a base 116, an elastic body 117, an adsorber 119, an input unit I, and an output unit O.

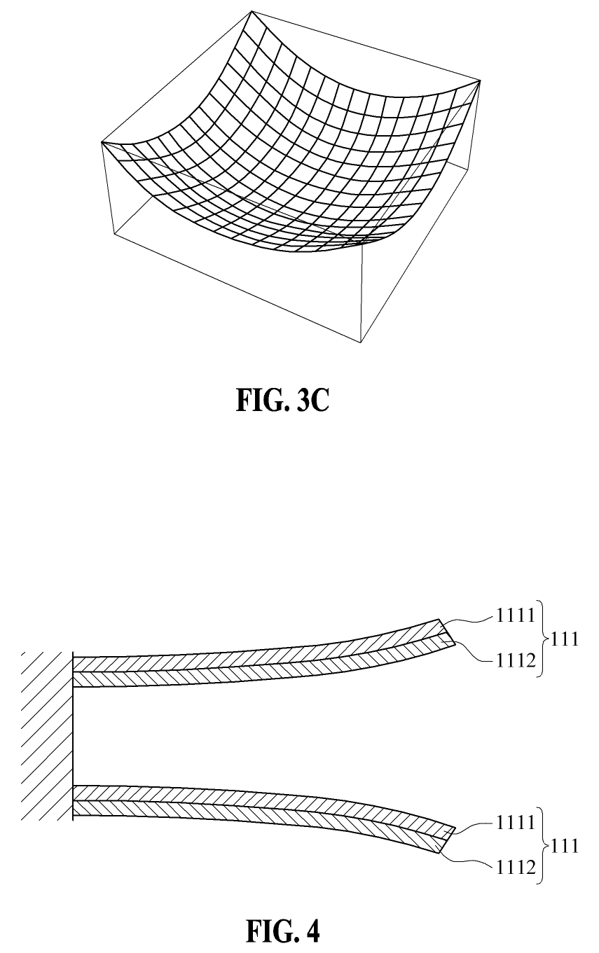

The membrane structure 111 may include a plurality of layers 1111 and 1112 having CTEs. The membrane structure 111 may include a first layer 1111 having a first CTE on which the wafer w may be placed, and a second layer 1112 having a second CTE different from the first CTE. According to such a structure, when the membrane structure 111 is heated or cooled, each region of the membrane structure 111 may be deformed in a specific direction. This will be described below with reference to FIG. 4. For example, the membrane structure 111 may include two layers 1111 and 1112, but it is not necessarily limited thereto and it is noted that the number of layers may be three or more. For example, a third layer (not shown) having a third CTE having a value between the first CTE and the second CTE may be disposed between the two layers 1111 and 1112.

The temperature controller 112 may heat or cool the membrane structure 111 to thermally deform the membrane structure. For example, the temperature controller 112 may include a heat conductor 1121 and a heat source 1122.

At least one heat conductor 1121 may be installed in contact with or adjacent to the membrane structure 111 to control the temperature of the membrane structure 111. When the number of heat conductors 1121 is more than one, at least some of the plurality of heat conductors 1121 may be controlled independently of the others. Through this, the plurality of heat conductors 1121 may independently heat or cool a plurality of regions of the membrane structure 111. The term "independently" is used to imply that the amount of heat provided or absorbed by each heat conductor 1121 may be independently controlled. For example, the plurality of different heat conductors 1121 may transfer heat to one region, or heat generated from one heat conductor 1121 may be transferred to a plurality of regions. The term "independently" in the present disclosure does not exclude the above cases. The heat conductor 1121 may be, for example, uniformly arranged over the entire region of the membrane structure 111. With this arrangement, a temperature of each region of the membrane structure 111 may be precisely controlled. For example, the controller 114 may control the heat source 1122 to heat or cool the heat conductor 1121 positioned at a lower side of each region of the membrane structure 111, thereby controlling the temperature of each region of the membrane structure 111. For example, the heat conductor 1121 may be installed to be positioned on a lower side of the membrane structure 111 through the elastic body 117. Through this structure, an installation length of the heat conductor 1121 may be reduced. In contrast, the heat conductor 1121 may also be installed to be positioned on the lower side of the membrane structure 111 by bypassing the elastic body 117 along an outer surface of the elastic body 117.

The heat conductor 1121 may include, for example, a heater that increases the temperature of the membrane structure 111 and/or a cooler that decreases the temperature of the membrane structure 111. The heat conductor 1121 may include, for example, a heating wire with a temperature increasing by electrical resistance, a fluid pipe that may heat or cool the temperature of a surrounding area through the circulation of a high-temperature or low-temperature fluid, or a Peltier element which is an electronic element that utilizes the Peltier effect.

The heat source 1122 may control the amount of heat that the heat conductor 1121 has, so that the heat conductor 1121 may function as a heater or a cooler. For example, when the heating wire is used as the heat conductor 1121, a power supply that applies a current to the heating wire may be used as the heat source 1122. When the fluid pipe is used as the heat conductor 1121, known means capable of heating or cooling the fluid circulating through the fluid pipe may be used as the heat source 1122. When the Peltier element is used as the heat conductor 1121, a power supply that supplies a current to the Peltier element may be used as the heat source 1122.

Although the case where the heat conductor 1121 is installed on the base 116 or the membrane structure 111 has been described as an example, the heat conductor 1121 may also be installed on the outside of the base 116 or the membrane structure 111. For example, the heat conductor 1121 may include a lamp capable of heating the membrane structure 111 from the outside of the membrane structure 111. For example, the heat conductor 1121 installed on the outside of the membrane structure 111 and the heat conductor 1121 installed in the membrane structure 111 may be driven together to deform the membrane structure 111.

The temperature sensor 113 may measure the temperature of each region of the membrane structure 111. Information measured by the temperature sensor 113 may be transmitted to the controller 114. The controller 114 may determine whether the temperature of each region of the membrane structure 111 has reached a target temperature based on the information measured by the temperature sensor 113. The target temperature herein may be understood to refer to a specific temperature value or a specific temperature range. The controller 114 may drive the temperature controller 112 based on the information detected by the temperature sensor 113.

The warpage sensor 115 may measure warpage information of the membrane structure 111. Information measured by the warpage sensor 115 may be transmitted to the controller 114. The controller 114 may compare the warpage information of the membrane structure 111 measured by the warpage sensor 115 with warpage information of the wafer w to determine whether the membrane structure 111 is deformed according to the shape of the wafer w. For example, the warpage sensor 115 may detect a size of a deviation of each region of the membrane structure 111 with respect to a reference plane of the membrane structure 111. The controller 114 may compare the deviation of each region of the membrane structure 111 with a deviation of each region of the wafer w, and determine that the deformation of the membrane structure 111 is complete, when a difference thereof is within a set value. In an example, the warpage sensor 115 may detect the size of the deviation described above using a non-contact optical sensor. The size of the deviation with respect to the reference plane may be, for example, an average value, a minimum value, or a maximum value of the deviation at each point where the warpage occurred. In another example, the warpage sensor 115 may detect the size of the deviation described above by detecting a strain of each region of the elastic body 117 supporting the membrane structure 111. For example, the warpage sensor 115 may include a strain gauge capable of detecting the strain of the elastic body 117.

The elastic body 117 may be installed between the membrane structure 111 and the base 116. The elastic body 117 may improve the durability of the membrane structure 111 by preventing it from directly contacting the base 116 during the process in which the membrane structure 111 is deformed. The elastic body 117 may have a stretchable and shrinkable material and/or structure, unlike the base 116 that is formed of a rigid material. Through this, the elastic body 117 may be stretched and shrunk (i.e., may expand and contract) in response to changes in height of the membrane structure 111 relative to the base 116. For example, the elastic body 117 may be formed as a rubber pad. The type of elastic body 117 is not limited thereto, and any material and/or structure that is freely stretchable and shrinkable (i.e., expandable and contractable) in a vertical direction to conform to the deformation of the membrane structure 111 may be applied. For example, the elastic body 117 may be formed of a material having a lower thermal conductivity than an average thermal conductivity of the membrane structure 111. With such a configuration, the heat exchange occurring between the elastic body 117 and the heat conductor 1121 may be reduced, and the heat transfer efficiency from the heat conductor 1121 to the membrane structure 111 may be improved.

The adsorber 119 may adsorb (i.e., securely hold) the wafer w onto the membrane structure 111. In a state where the membrane structure 111 is deformed according to the shape of the wafer w, the controller 114 may drive the adsorber 119 to adsorb the wafer w onto the membrane structure 111. In an example, the adsorber 119 may adsorb the wafer w using an electrostatic force. The adsorber 119 may include an adsorption electrode 1191 and a power supply 1192.

The adsorption electrode 1191 may be disposed on the lower side of the membrane structure 111 and may accumulate charge by receiving a voltage. The power supply 1192 may control a magnitude of the voltage applied to the adsorption electrode 1191. The adsorption electrode 1191 may be installed, for example, on the base 116, but alternatively, it may also be installed on the elastic body 117. The case where the wafer chucking system 11 adsorbs the wafer w by an electrostatic chuck arrangement has been described as an example, however, the wafer chucking system 11 may also adsorb the wafer w by a vacuum chuck arrangement as will be described below.

The input unit I may transmit information received from a manager of the wafer chucking system 11 or an external electronic device to the controller 114. For example, the input unit I may receive the warpage information of the wafer w. The controller 114 may set the target temperature of each region of the membrane structure 111 and drive the temperature controller 112 based on the warpage information received from the input unit I. In another example, the input unit I may receive a temperature and/or a deformation time for each region of the membrane structure 111, and accordingly, the controller 114 may drive the temperature controller 112.

The output unit O may output deformation information of the membrane structure 111 to the manager of the wafer chucking system 11 or an external electronic device (e.g., a portable terminal of the manager). The deformation information may include, for example, information about whether the membrane structure 111 is deformed according to the shape of the warpage of the wafer w, or shape information of the membrane structure 111. For example, the output unit O may output the deformation information of the membrane structure 111 in at least one of a visual form, an auditory form, or a tactile form.

The controller 114 may control the temperature controller 112, the adsorber 119, and the output unit O based on information received from the temperature sensor 113, the warpage sensor 115, and the input unit I. For example, the controller 114 may be a computing device such as a workstation computer, a desktop computer, a laptop computer, or a tablet computer. The controller 114 may be a processor such as a simple controller, microprocessor, a central processing unit (CPU), or a graphics processing unit (GPU). For example, the controller 114 may be implemented using a general-purpose computer or application-specific hardware such as a digital signal processor (DSP), a field programmable gate array (FPGA), or an application specific integrated circuit (ASIC). For example, the operations of the controller 114 may be implemented as instructions stored in a machine-readable medium that may be read and executed by one or more processors. Here, a machine-readable medium may include any mechanism for storing and/or transmitting information in a form readable by a machine (e.g., a computing device). For example, a machine-readable medium may include a read only memory (ROM), a random access memory (RAM), a magnetic disk storage medium, an optical storage medium, a flash memory device, and the like.

FIG. 4 is a conceptual diagram illustrating a deformation principle of a membrane structure according to an embodiment.

Referring to FIG. 4, the CTE of the first layer 1111 disposed on an upper side of the membrane structure 111 according to an embodiment may have a higher value than the CTE of the second layer 1112 disposed on a lower side of the membrane structure 111. In this case, when the membrane structure 111 is cooled, the first layer 1111 having a higher CTE shrinks or contracts more than the second layer 1112, so that a free end of the membrane structure 111 changes to be bent upward, as shown in the upper part of FIG. 4. In this way, the membrane structure 111 may be deformed according to smile-shaped warpage shown in FIG. 3C.

When the membrane structure 111 is heated, the first layer 1111 having a higher CTE expands more than the second layer 1112, so that the free end of the membrane structure 111 changes to be bent downward, as shown in the lower part of FIG. 4. In this way, the membrane structure 111 may be deformed according to crying-shaped warpage shown in FIG. 3B.

When the CTE of the first layer 1111 has a lower value than the CTE of the second layer 1112, the membrane structure 111 may be deformed into a desired shape by heating or cooling in the opposite manner to the method described above. This is a matter that may be easily understood by those skilled in the art, and therefore a detailed description thereof will be omitted.

Similarly, when the membrane structure 111 is heated or cooled for each region, the membrane structure 111 may be deformed for each region according to the smile-shaped warpage and the crying-shaped warpage. In other words, the membrane structure 111 may be deformed according to the saddle-shaped warpage as shown in FIG. 3A.

For example, as a material with a low CTE, an alloy of nickel (Ni) and iron (Fe) may be used. For example, INVAR®, which is a material with a low CTE and contains 63.5% of iron and 36.5% of nickel, may be used. The composition ratio of INVAR® is not necessarily limited thereto, and the composition ratio of iron and nickel may vary. For example, a material with a high CTE may include (i) an alloy of nickel (Ni), manganese (Mn), and iron (Fe), (ii) an alloy of nickel (Ni), molybdenum (Mo), and iron (Fe), and (iii) an alloy of nickel (Ni), manganese (Mn), and copper (Cu). These are merely examples, and any materials may be used as long as the CTEs of the plurality of layers 111 and 1112 are different from each other. For example, a pair of layers 1111 and 1112 may be formed of a combination of INVAR®-copper, INVAR®-nickel, or copper-iron.

When the membrane structure 111 having the plurality of layers 1111 and 1112 having different CTEs is used, the membrane structure 111 may be deformed according to various warpage shapes of the wafer, which is a chucking target, by heating or cooling the membrane structure 111 for each region.

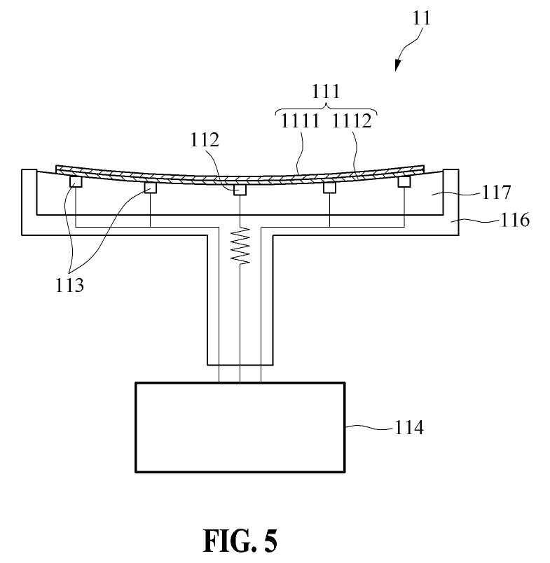

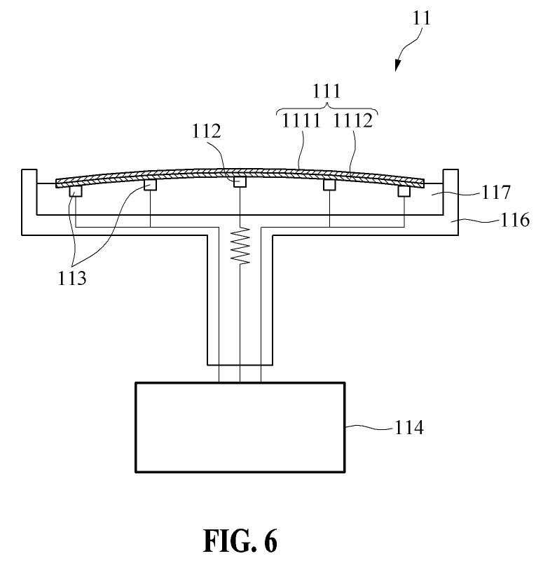

FIG. 5 is a diagram illustrating a membrane structure deformed to have a smile warpage shape by using a wafer chucking system according to an embodiment, and FIG. 6 is a diagram illustrating a membrane structure deformed to have a crying warpage shape by using a wafer chucking system according to an embodiment.

Referring to FIG. 5, when a CTE of an upper layer 1111 of the membrane structure 111 has a higher value than a CTE of a lower layer 1112, the controller 114 of the wafer chucking system 11 according to an embodiment may deform the membrane structure 111 into a smile shape by driving the temperature controller 112 to cool the membrane structure 111.

When the CTE of the upper layer 1111 of the membrane structure 111 has a lower value than the CTE of the lower layer 1112, the controller 114 may deform the membrane structure 111 into a smile shape by driving the temperature controller 112 to heat the membrane structure 111.

Referring to FIG. 6, when the CTE of the upper layer 1111 of the membrane structure 111 has a higher value than the CTE of the lower layer 1112, the controller 114 of the wafer chucking system 11 according to an embodiment may deform the membrane structure 111 into a crying shape by driving the temperature controller 112 to cool the membrane structure 111.

When the CTE of the upper layer 1111 of the membrane structure 111 has a lower value than the CTE of the lower layer 1112, the controller 114 may deform the membrane structure 111 into a crying shape by driving the temperature controller 112 to cool the membrane structure 111.

When the wafer has saddle-shaped warpage, the controller 114 may deform the membrane structure 111 into a saddle shape by driving the temperature controller 112 to heat or cool the membrane structure 111 for each region according to the shape of the wafer.

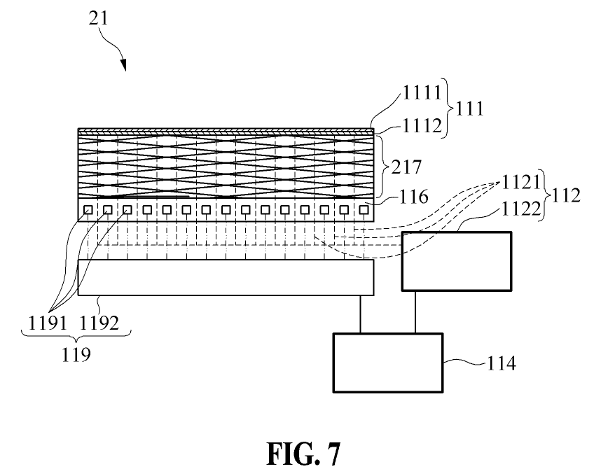

FIG. 7 is a diagram illustrating a wafer chucking system according to an embodiment.

Referring to FIG. 7, a wafer chucking system 21 according to an embodiment may include the membrane structure 111 including the plurality of layers 1111 and 1112, the temperature controller 112 including the heat conductor 1121 and the heat source 1122, the controller 114, the base 116, an elastic body 217, and the adsorber 119 including the adsorption electrode 1191 and the power supply 1192.

The elastic body 217 may be formed of a porous medium having elasticity. For example, the elastic body 217 may be a metal sponge or a mesh net. For example, when the elastic body 217 has a vertically empty space inside, the heat conductor 1121 may be installed in the empty space described above. In other words, there is no need to form a separate path through which the heat conductor 1121 passes inside the elastic body 217.

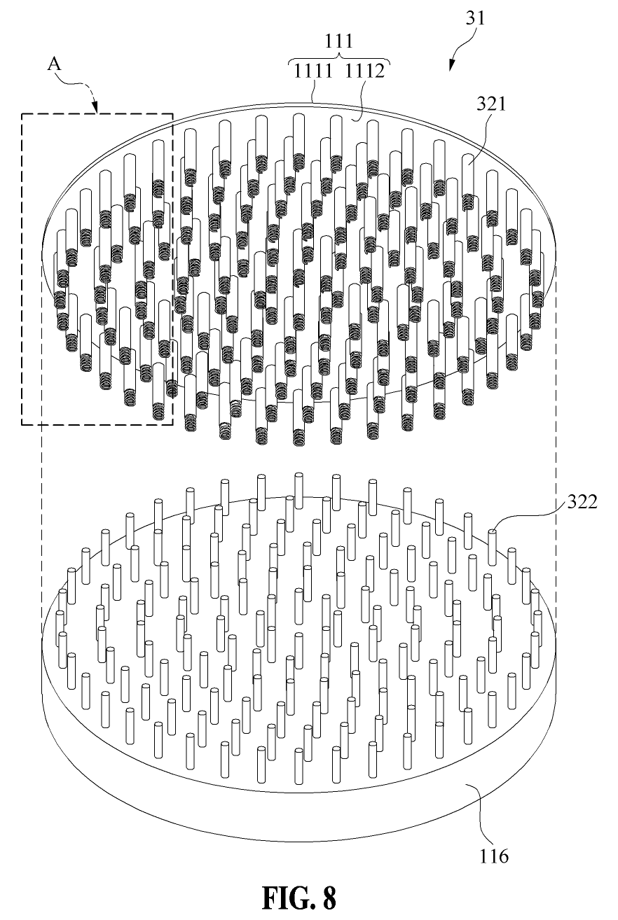

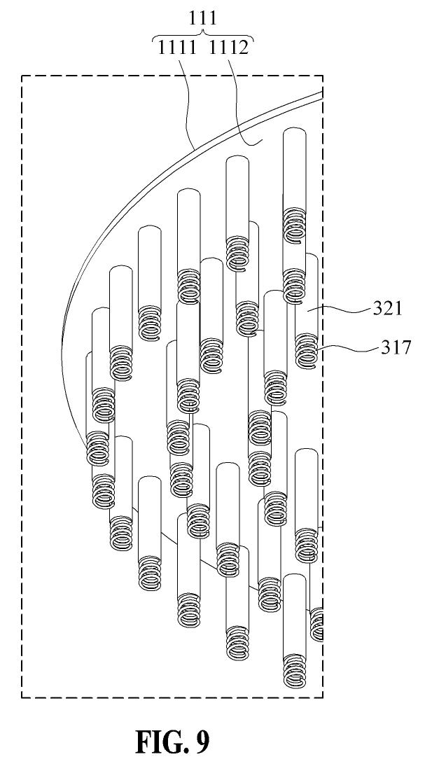

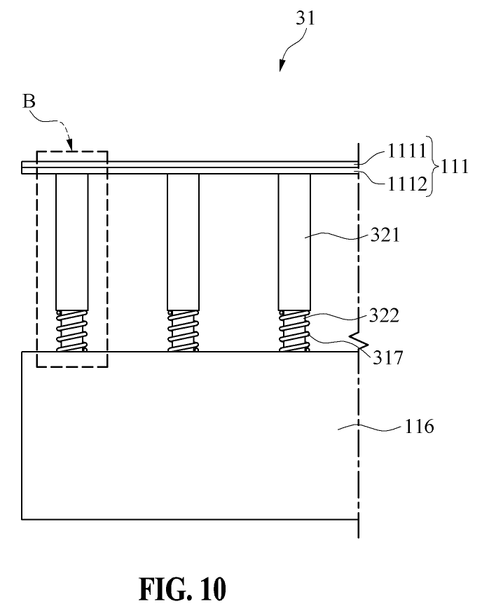

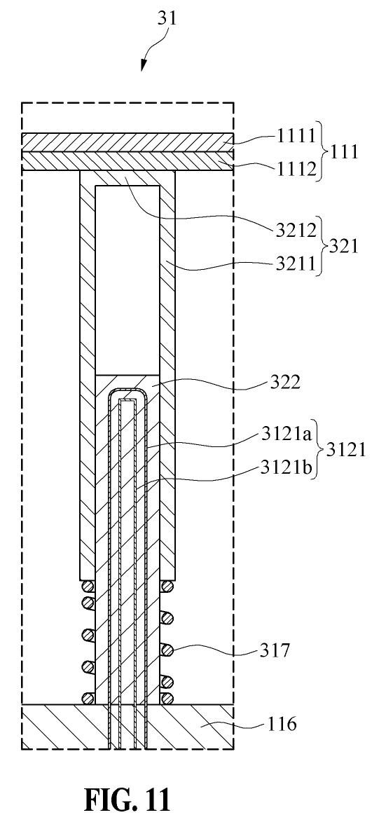

FIG. 8 is a perspective view of a wafer chucking system according to an embodiment, FIG. 9 is an enlarged view of section A of FIG. 8, FIG. 10 is a side view of a wafer chucking system according to an embodiment, and FIG. 11 is a cross-sectional view according to an embodiment of section B of FIG. 10.

Referring to FIGS. 8 to 11, a wafer chucking system 31 according to an embodiment may include the membrane structure 111 including the first layer 1111 and the second layer 1112, the temperature controller including the heat conductor 1121 and a heat source (not shown), the base 116, an elastic body 317, a floating rod 321, and a sliding guide 322.

The floating rod 321 may be installed on the second layer 1112 forming a lower surface of the membrane structure 111. The floating rod 321 may be formed to be vertically elongated downward from the second layer 1112 and may slide along the sliding guide 322. Through this structure, the floating rod 321 may slide along the sliding guide 322 while conforming to the deformation of the membrane structure 111. For example, the floating rod 321 may be fixed to be in surface contact with the second layer 1112. In a case of a point contact method, stress may be concentrated in a local region of the membrane structure 111, which may cause damage to the membrane structure 111. However, since the stress applied to the membrane structure 111 may be relatively dispersed by the surface contact method, the durability and service life of the membrane structure 111 may be increased. Through this method, the membrane structure 111 may be continuously deformed and used according to various semiconductor processes and warpage shapes. For example, an accommodation space that may accommodate the sliding guide 322 may be formed inside the floating rod 321. In other words, the floating rod 321 may be formed to have a larger diameter than the sliding guide 322. According to this structure, a contact area between the floating rod 321 and the second layer 1112 may be further increased. The floating rod 321 may include a pillar portion 3211 that surrounds the internal accommodation space formed inside, and a bottom portion 3212 that surrounds one surface of the pillar portion 3211. For example, the bottom portion 3212 may be in surface contact with the second layer 1112 (i.e., the pillar portion 3211 is cylindrical with an internal space configured to receive the sliding guide 322). When the bottom portion 3212 is provided, a surface contact area between the floating rod 321 and the membrane structure 111 may be further increased.

The sliding guide 322 may be installed on the base 116. The sliding guide 322 may be formed to be vertically elongated from an upper surface of the base 116 toward the membrane structure 111 and may guide a sliding direction of the floating rod 321. According to this structure, a vertical distance between each region of the membrane structure 111 and the base 116 may be changed according to the deformation of the membrane structure 111.

The elastic body 317 may be installed between the membrane structure 111 and the base 116, and may be compressed according to a sliding distance between the floating rod 321 and the sliding guide 322. In other words, the elastic body 317 may be stretched and shrunk in response to a change in a height of each region of the membrane structure 111 relative to the base 116. The elastic body 317 may prevent the floating rod 321 from directly colliding with the base 116 or the sliding guide 322 from directly colliding with the membrane structure 111. The elastic body 317 may be provided as, for example, a compression spring. For example, the elastic body 317 may be disposed to surround the periphery of the sliding guide 322, and both ends may be supported by the floating rod 321 and the base 116, respectively.

The floating rod 321, the sliding guide 322, and the elastic body 317 described above may be collectively referred to as an "elastic support structure". The elastic support structure 321, 322, and 317 may be stretched and shrunk in response to the change in height of each region of the membrane structure 111 relative to the base 116 while preventing the base 116 and the membrane structure 111 from directly contacting each other during the process of deformation of the membrane structure 111. The elastic support structure 321, 322, and 317 may be arranged in plurality between the membrane structure 111 and the base 116, for example (i.e., there may be a plurality of floating rods 321 and a plurality of corresponding sliding guides 322 operably associated therewith, as illustrated in FIGS. 8-10).

A heat conductor 3121 may be formed inside the elastic support structure 321, 322, and 317 as shown in FIG. 11. According to this structure, the amount of heat leaking out from the heat conductor 3121 to the outside may be reduced, and the heat transfer efficiency from the heat conductor 3121 to the membrane structure 111 may be improved. For example, the floating rod 321 may be formed of a material having a lower thermal conductivity than the average thermal conductivity of the membrane structure 111 to further improve the heat transfer efficiency.

For example, the heat conductor 3121 may be installed in the sliding guide 322 and may heat or cool the second layer 1112 through the sliding guide 322 and the floating rod 321. According to this structure, regardless of the distance between the floating rod 321 and the sliding guide 322, the heat conductor 3121 may maintain a fixed position within the sliding guide 322. Therefore, the installability of the heat conductor 3121 may be improved, and the durability of the heat conductor 3121 after installation may also be improved, thereby increasing the service life of the overall wafer chucking system 31. The heat conductor 3121 may include, for example, a heater 3121a and a cooler 3121b.

Unlike as shown in the drawings, the heat conductor 3121 may be installed outside the elastic support structure 321, 322, and 317. For example, the heat conductor 3121 may be arranged to connect the membrane structure 111 and the base 116 in the empty space between the elastic support structure 321, 322, and 317 described above.

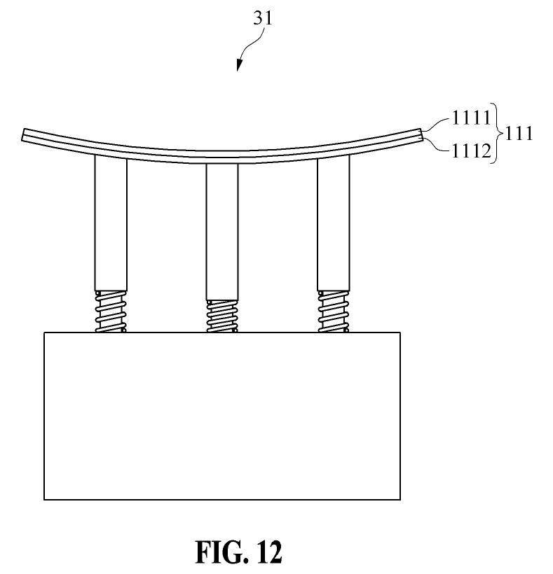

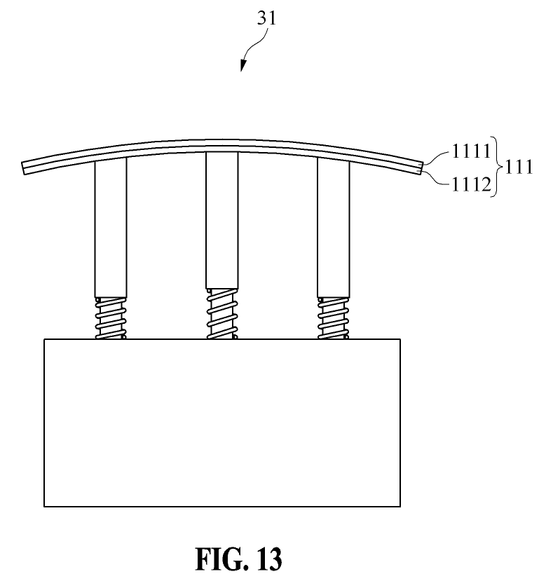

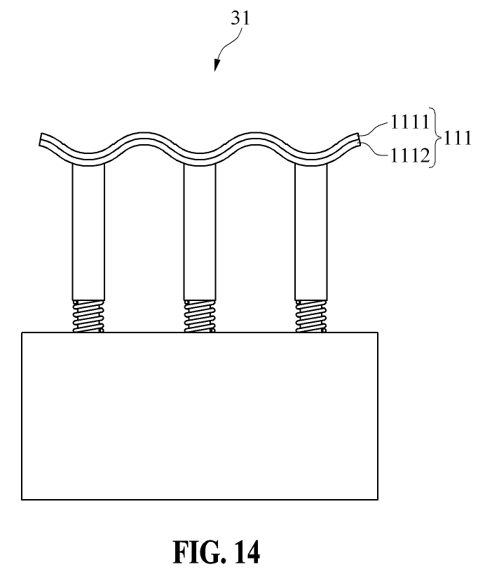

FIG. 12 is a diagram illustrating a membrane structure deformed to have a smile warpage shape by using a wafer chucking system according to an embodiment, FIG. 13 is a diagram illustrating a membrane structure deformed to have a crying warpage shape by using a wafer chucking system according to an embodiment, and FIG. 14 is a diagram illustrating a membrane structure deformed to have a wave warpage (i.e., an undulating) shape by using a wafer chucking system according to an embodiment.

Referring to FIGS. 11 to 14, the drawings show that the elastic support structure 321, 322, and 317 changes in various ways according to the thermal deformation of the membrane structure 111. When the floating rod 321 is in point contact with the second layer 1112, there is a possibility that damage may occur to the membrane structure 111 during the process as shown in FIGS. 12 to 14, however, the damage to the membrane structure 111 may be reduced through the surface contact structure.

According to the thermal deformation of the membrane structure 111, not only a vertical distance between the membrane structure 111 and the base 116, but also a minute distance change may occur locally in a horizontal direction. In order to conform such changes, at least one of the floating rod 321 and the sliding guide 322 may be formed of a flexible material. For example, the floating rod 321 may be formed of a material that is flexible, such as rubber, but has a lower thermal conductivity than the membrane structure 111. According to this configuration, the floating rod 321 may maintain stable surface contact with the second layer 1112 by conforming to the minute horizontal distance change that occurs locally on the lower surface of the membrane structure 111. In addition, since heat leaking to the outside from the heat conductor 3121 may be reduced, it also helps to improve the heat transfer efficiency from the heat conductor 3121 to the membrane structure 111.

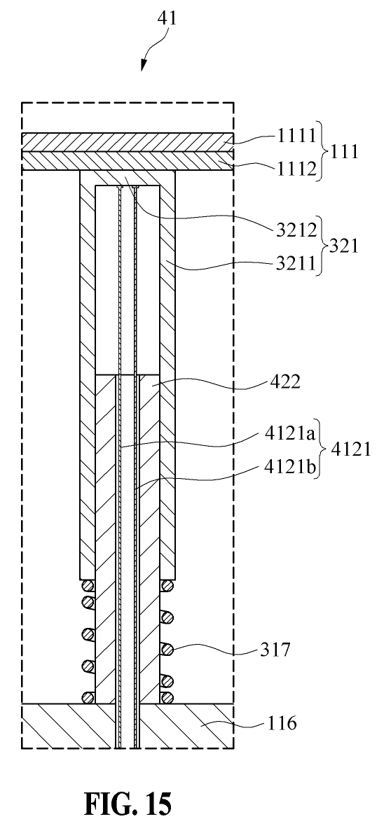

FIG. 15 is a cross-sectional view according to an embodiment of section B of FIG. 10.

Referring to FIG. 15, a wafer chucking system 41 according to an embodiment may include the membrane structure 111 including the first layer 1111 and the second layer 1112, a temperature controller including a heat conductor 4121 and a heat source (not shown), the base 116, the elastic body 317, the floating rod 321, and a sliding guide 422.

For example, the heat conductor 4121 may be directly connected to the floating rod 321 through the sliding guide 422. As shown in the drawing, the heat conductor 4121 may be connected to the bottom portion 3212 of the floating rod 321. According to this structure, a problem of heat transferred from the heat conductor 4121 leaking to the outside through the pillar portion 3211 of the floating rod 321 may be reduced. The heat conductor 4121 may be connected to the pillar portion 3211 of the floating rod 321 or may be directly connected to the second layer 1112 through both the sliding guide 422 and the floating rod 321. The heat conductor 4121 may include, for example, a heater 4121a and a cooler 4121b.

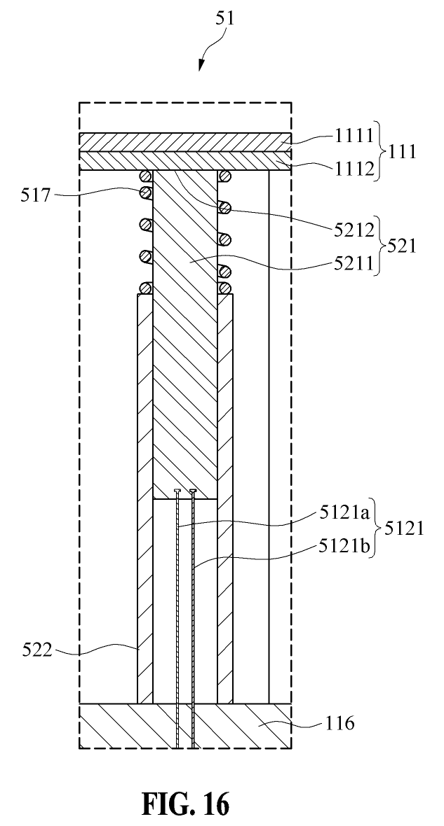

FIG. 16 is a cross-sectional view according to an embodiment of section B of FIG. 10.

Referring to FIG. 16, a wafer chucking system 51 according to an embodiment may include the membrane structure 111 including the first layer 1111 and the second layer 1112, a temperature controller including a heat conductor 5121 and a heat source (not shown), the base 116, an elastic body 517, a floating rod 521, and a sliding guide 522.

As shown in the drawing, the sliding guide 522 may be formed to have a diameter larger than that of the floating rod 521 and may have an accommodation space that may accommodate the floating rod 521 inside. The elastic body 517 may be disposed to surround the periphery of the floating rod 521, and both ends may be supported by the second layer 1112 and the sliding guide 522, respectively, as illustrated.

The heat conductor 5121 may be directly connected to a pillar portion 5211 of the floating rod 521 through the sliding guide 522. In contrast, the heat conductor 5121 may be directly connected to a bottom portion 5212 of the floating rod 521 through the pillar portion 5211 of the floating rod 521. For example, the heat conductor 5121 may be directly connected to the second layer 1112 through the floating rod 521. The heat conductor 5121 may include, for example, a heater 5121a and a cooler 5121b.

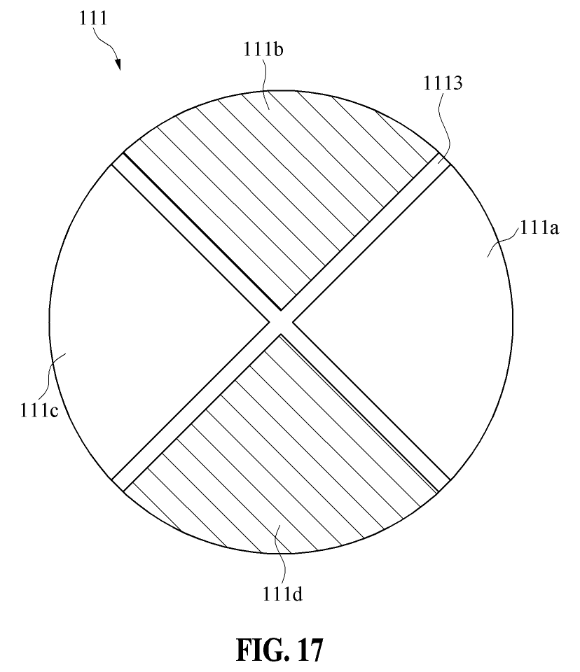

FIG. 17 is a diagram illustrating a method of controlling a temperature for each region of a membrane structure 111 according to an embodiment.

Referring to FIG. 17, the membrane structure 111 according to an embodiment may include a plurality of regions 111a, 111b, 111c, and 111d sectioned from each other, and an insulating material 1113 disposed between the plurality of regions.

A temperature controller (112, see FIG. 1) may independently heat or cool each of the plurality of regions 111a to 111d by using a plurality of heat conductors (1121, see FIG. 1) respectively connected to or arranged adjacent to the plurality of regions 111a to 111d.

The membrane structure 111 may be sectioned into various shapes. For example, as shown in FIG. 17, the plurality of regions 111a to 111d may be arranged in plurality (e.g., four) in an angular direction from a point (e.g., a center point) of the membrane structure 111. According to this structure, the membrane structure 111 may be thermally deformed into a shape identical or similar to the saddle-shaped warpage as shown in FIG. 3A. For example, by heating or cooling some regions (e.g., the first region 111d and the third region 111b) that are spaced apart from each other in the angular direction among the plurality of regions 111a to 111d at a temperature that is different from a temperature for the remaining regions (e.g., the second region 111c and the fourth region 111a), the some regions (e.g., the first region 111d and the third region 111b) may be deformed to have a crying-shaped warpage, and the remaining regions (e.g., the second region 111c and the fourth region 111a) may be deformed to have a smile-shaped warpage.

FIG. 17 shows that each region has the same angle (e.g., each of the illustrated regions forms a 90° angle at the center point), but this is merely an example, and the angle of each region may vary depending on the warpage shape of an actual chucking target wafer. In addition, although FIG. 17 shows that the total number of the sectioned regions is 4, this is merely an example, and the number of sectioned regions may be 3 or less or 5 or more. For example, when the membrane structure 111 is sectioned into two regions and the temperature is controlled differently for each sectioned region, the membrane structure 111 may be thermally deformed to have a warpage shape in which both sides are bent upward or downward from a straight axis.

The insulating material 1113 may reduce the amount of heat conducted between the plurality of regions 111a to 111d. For example, when the heating or cooling time for the thermal deformation of the membrane structure 111 increases, heat transfer may occur between each region in a direction in which thermal equilibrium is performed in the membrane structure 111 itself. The insulating material 1113 may help reduce the thermal equilibrium problem and precisely thermally deform the membrane structure 111 into a desired shape. Unless otherwise stated, the membrane structure 111 does not necessarily have to include the insulating material 1113.

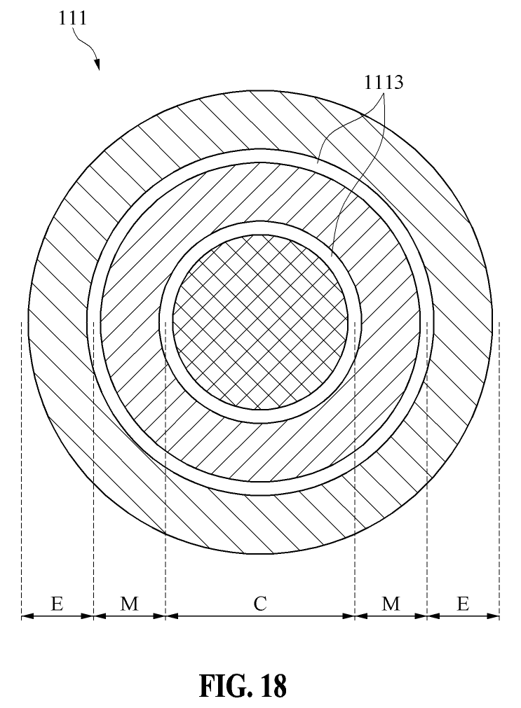

FIG. 18 is a diagram illustrating a method of controlling a temperature for each region of a membrane structure according to an embodiment.

Referring to FIG. 18, the membrane structure 111 according to an embodiment may include a plurality of regions C, M, and E arranged radially from a point (e.g., a center point) of the membrane structure 111, and the insulating material 1113 arranged between the plurality of regions C, M, and E.

The plurality of regions C, M, and E may include a central region C positioned closest to the center point of the membrane structure 111, an edge region E positioned at the edge of the membrane structure 111, and a middle region M positioned between the central region C and the edge region E. By setting a target temperature and/or a deformation time differently for each region sectioned as described above, the membrane structure 111 may be deformed into the crying shape shown in FIG. 3B or the smile shape shown in FIG. 3C.

For example, the warpage shape of the wafer may have a shape in which a curvature increases from the center to the edge. In this case, the membrane structure 111 may be deformed according to a desired curvature by setting the target temperature and/or the deformation time of the edge region E to be greater than the target temperature and/or the deformation time of the central region C. For example, the target temperature and/or the deformation time of the middle region M may be set to be greater than the target temperature and/or the deformation time of the central region C and lower than the target temperature and/or the deformation time of the edge region E.

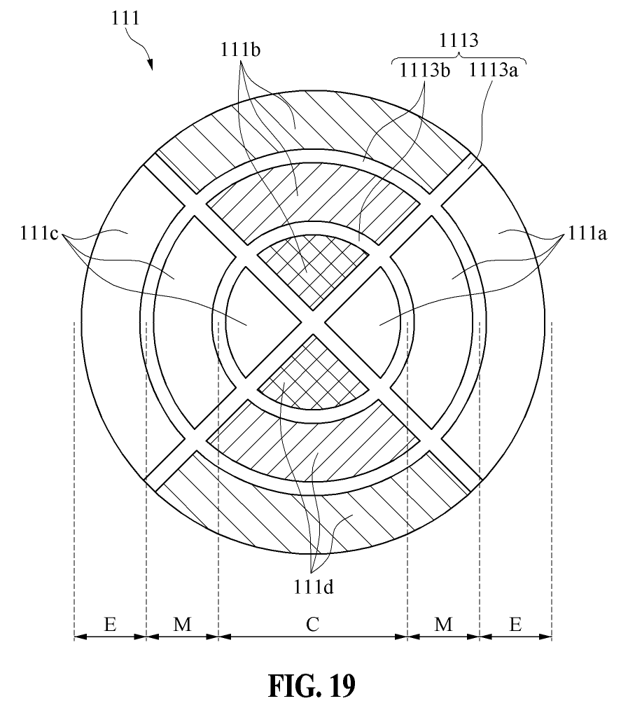

FIG. 19 is a diagram illustrating a method of controlling a temperature for each region of a membrane structure 111 according to an embodiment.

Referring to FIG. 19, it may be understood that the membrane structure 111 according to an embodiment is obtained by a combination of the sectioning methods described with reference to FIGS. 17 and 18. The membrane structure 111 may include the plurality of regions 111a, 111b, 111c, and 111d arranged in plurality (e.g., four) in an angular direction from one point (e.g., a center point) of the membrane structure 111. At least a portion of the plurality of regions 111a, 111b, 111c, and 111d may be sub-sectioned into, as shown in the drawing, a central region C positioned at the center of the membrane structure 111 in a radial direction, an edge region E positioned at the edge of the membrane structure 111, and a middle region M positioned between the central region C and the edge region E. In other words, at least some of the plurality of regions 111a, 111b, 111c, and 111d may include a plurality of sub-regions C, M, and E that are radially sectioned from a point (e.g., the center point) of the membrane structure 111. In contrast, the membrane structure 111 may include the plurality of regions C, M, and E that are sectioned in the radial direction, and at least some of the plurality of regions C, M, and E may include a plurality of sub-regions 111a, 111b, 111c, and 111d that are sectioned in the angular direction from one point (e.g., the center point) of the membrane structure 111.

By heating or cooling the plurality of sub-regions sectioned as described above at different temperatures, the membrane structure 111 may be thermally deformed into a warpage shape with a more complex shape. In addition, the same membrane structure 111 may be used to (i) independently control the temperature for each region sectioned in the angular direction, and/or (ii) independently control the temperature for each region sectioned in the radial direction. In other words, by using the same membrane structure 111, the membrane structure 111 may be thermally deformed according to the saddle-shaped warpage as shown in FIG. 3A, or the membrane structure 111 may be thermally deformed according to the crying-shaped warpage as shown in FIG. 3B or the smile-shaped warpage as shown in FIG. 3C. In other words, it is possible to respond to wafers having different shapes of warpage without replacing the wafer chucking system in the same semiconductor process equipment.

The method of sectioning the membrane structure 111 in the angular direction and/or radial direction has been described above, however, the method of sectioning the membrane structure 111 is not limited thereto. For example, the membrane structure 111 may have a plurality of regions arranged in parallel with each other on the membrane structure 111. According to this structure, the membrane structure 111 may be deformed into a wave pattern shape as shown in FIG. 14. It is noted that the sectioned shape of the regions of the membrane structure 111 may be set in various ways by considering the warpage shape of the wafer.

The insulating material 1113 may include an angularly sectioned insulating material 1113a disposed between the plurality of regions 111a, 111b, 111c, and 111d that are sectioned in the angular direction, and a radially sectioned insulating material 1113b disposed between the plurality of radially sectioned regions C, M, and E. The insulating material 1113 may reduce a degree of heat exchange between each sub-sectioned region to heat or cool each region to a set level so that the membrane structure 111 is precisely deformed.

Although the case where each of the layers 1111 and 1112 of the membrane structure 111 has the same CTE regardless of the region for each layer has been described as an example, it is not necessarily limited thereto. As described below, different regions within the same layer may have different CTEs.

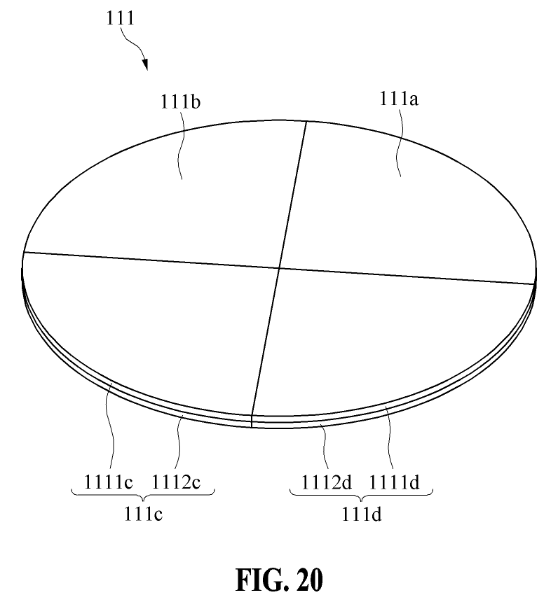

FIG. 20 is a perspective view illustrating a membrane structure according to an embodiment.

Referring to FIG. 20, the membrane structure 111 according to an embodiment may include the plurality of regions 111a, 111b, 111c, and 111d that are sectioned from each other. For example, a CTE of a layer 1111d disposed on an upper side of the first region 111d among the plurality of regions 111a, 111b, 111c, and 111d may have a higher value than a CTE of a layer 1112d disposed on a lower side of the first region 111d. For example, a CTE of a layer 1111c disposed on an upper side of the second region 111c adjacent to the first region 111d among the plurality of regions 111a, 111b, 111c, and 111d may have a lower value than a CTE of a layer 1112c disposed on a lower side of the second region 111c. For example, the CTE of the layer 1111d disposed on the upper side of the first region 111d may be the same as the CTE of the layer 1112c disposed on the lower side of the second region 111c, and the CTE of the layer 1112d disposed on the lower side of the first region 111d may be the same as the CTE of the layer 1111c on the upper side of the second region 111c. According to this configuration, even when the membrane structure 111 is heated to the same temperature, the first region 111d changes into the crying shape as the layer 1111d disposed on the upper side expands more than the layer 1112d disposed on the lower side. The second region 111c changes into the smile shape as the layer 1112c disposed on the lower side expands more than the layer 1111c disposed on the upper side. Similarly, when the third region 111b spaced apart from the first region 111d in an angular direction is formed to have the same arrangement and material as the first region 111d, and the fourth region 111a spaced apart from the second region 111c in an angular direction is formed to have the same arrangement and material as the second region 111c, it is possible to deform the membrane structure 111 into the saddle shape as shown in FIG. 3A simply by heating or cooling the entire region of the membrane structure 111.

In other words, adjacent regions within the same layer (e.g., the upper layer or the lower layer) may be formed of materials having different CTEs. According to such a structure, even when the entire region is heated or cooled to the same temperature, the shape of each region may change differently. In the membrane structure 111 according to the embodiment described above, it is not necessary to heat or cool the entire region to the same temperature. For example, a curvature of each region may be adjusted by differently setting the temperature of each region of the membrane structure 111. An insulating material may be provided between each region for precise temperature control for each region.

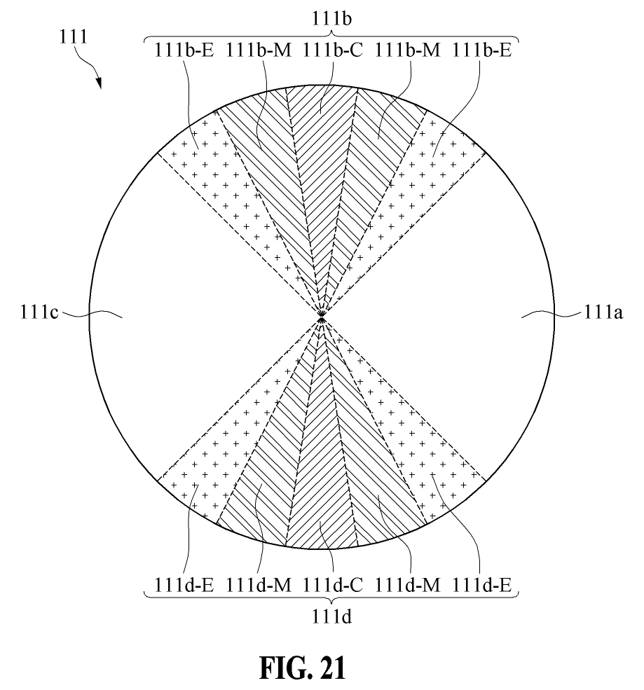

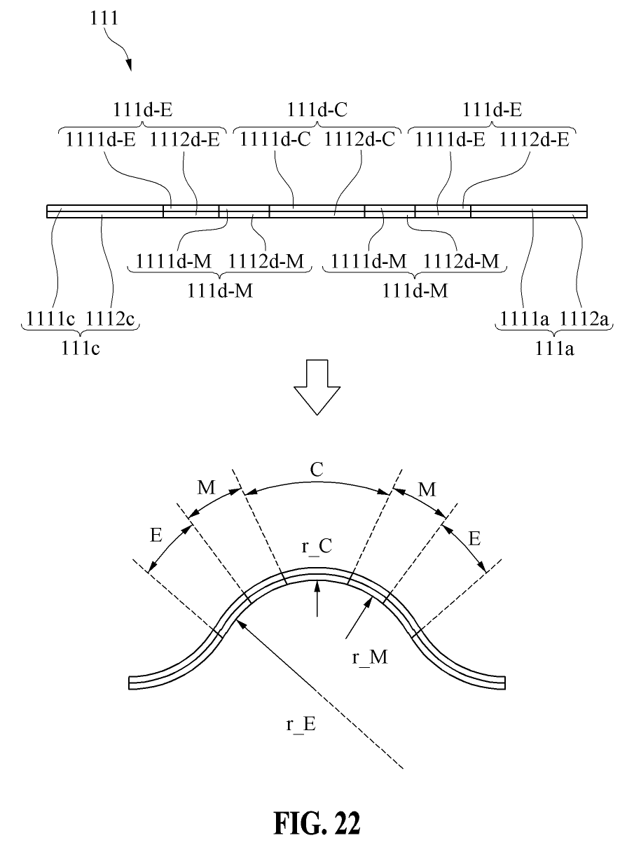

FIG. 22 is a side view illustrating a membrane structure and a deformed membrane structure according to an embodiment, and FIG. 21 is a top view of a membrane structure according to an embodiment.

Referring to FIGS. 21 and 22, the membrane structure 111 according to an embodiment may be deformed to have different curvatures for each region in angular directions. For example, the membrane structure 111 may be deformed according to a wafer having a saddle-shaped warpage.

A curvature is expressed as the reciprocal of a radius of curvature, and the larger the curvature (i.e., the greater the bending), the smaller the radius of curvature. Here, the radius of curvature refers to a radius of an imaginary circle drawn at any position on a curved surface or a curve that is bent to the same degree as a curve passing through that position.

The typical saddle-shaped warpage may be divided into two shapes by region, namely, regions having a crying shape and a smile shape. In a region having one of these shapes (e.g., the crying shape), the central region C positioned at the center of the region has a smallest radius of curvature r_C, the edge region E positioned at the edge of the region has a largest radius of curvature r_E, and a radius of curvature r_M of the middle region M positioned in the middle of the regions has a value therebetween. According to the membrane structure 111 according to an embodiment, the membrane structure 111 may be precisely deformed according to the curvature of each region.

The membrane structure 111 may be sectioned into the plurality of regions 111a, 111b, 111c, and 111d according to the warpage shape of the wafer. For example, the first region 111d and the third region 111b may be regions that are deformed in response to the crying shape, and the second region 111c and the fourth region 111a may be regions that are deformed in response to the smile shape. Among the plurality of regions 111a, 111b, 111c, and 111d, the first region 111d and the third region 111b corresponding to the same warpage shape (e.g., the crying warpage shape) may be specifically sectioned into central regions 111d-C and 111b-C, middle regions 111d-M and 111b-M, and edge regions 111d-E and 111b-E along the angular direction, respectively. By setting target temperatures and/or deformation times differently for each region specifically sectioned as described above, the changes of the amount of heat in the sub-regions C, M, and E of the wafer may be set to be different.

A difference in CTEs of the two layers 1111d-C and 1112d-C respectively disposed on the upper and lower sides of the central region 111d-C may be greater than a difference in CTEs of the two layers 1111d-M and 1112d-M respectively disposed on the upper and lower sides of the middle region 111d-M. Similarly, the difference in CTEs of the two layers 1111d-M and 1112d-M respectively disposed on the upper and lower sides of the middle region 111d-M may be greater than a difference in CTEs of the two layers 1111d-E and 1112d-E respectively disposed on the upper and lower sides of the edge region 111d-E. According to this configuration, even when heated or cooled to the same temperature, it may be deformed to have a large curvature in the order of the center region 111d-C, the middle region 111d-M, and the edge region 111d-E.

Hereinabove, the case where the curvature varies by region depending on the angular direction within the same warpage shape (e.g., the crying warpage shape) has been described as an example, however, it is not necessarily limited thereto. It may be easily understood by those skilled in the art that, even in other cases, the deformation may be performed with different curvature for each region by varying a difference between CTEs of upper and lower layers for each region.

In other words, in order to perform the deformation with different curvature for each region, a plurality of regions may be variously sectioned according to curvatures used for the deformation. In this state, a difference in CTEs of two layers respectively disposed on upper and lower sides of a first region among the plurality of regions may have a different value from a difference in CTEs of two layers respectively disposed on upper and lower sides of a second region adjacent to the first region among the plurality of regions.

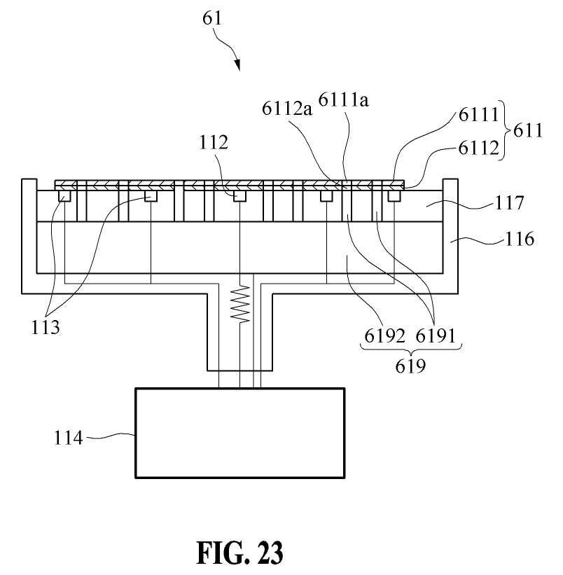

FIG. 23 is a side view of a wafer chucking system according to an embodiment.

Referring to FIG. 23, a wafer chucking system 61 according to an embodiment may adsorb a wafer in a vacuum chuck manner. For example, the wafer chucking system 61 may include a membrane structure 611, the temperature controller 112, the temperature sensor 113, the controller 114, the base 116, the elastic body 117, and an adsorber 619.

The membrane structure 611 may include a first layer 6111 and a second layer 6112. The first layer 6111 and the second layer 6112 may include a first adsorption hole or aperture 6111a and a second adsorption hole or aperture 6112a that communicate with each other, respectively (i.e., the first adsorption aperture and the second adsorption aperture are in fluid communication with each other). The first adsorption aperture 6111a and the second adsorption aperture 6112a provide a path for applying a negative pressure to a wafer to be placed on an upper surface of the first layer 6111, and may be formed in plurality over the entire region of the membrane structure 611, as illustrated in FIG. 23.

The adsorber 619 may adsorb the wafer using, for example, a vacuum pressure. The adsorber 619 may include an adsorption line 6191 and a vacuum pump 6192.

The adsorption line 6191 may connect the vacuum pump 6192 and the membrane structure 611, and may be communicated with the first adsorption hole 6111a and the second adsorption hole 6112a, so as to provide a negative pressure to the wafer positioned on the first layer 6111. For example, when the elastic body 117 is a rubber pad, a path may be formed to penetrate the rubber pad and the path may be used as the adsorption line 6191. In another example, the adsorption line 6191 may have a separate outer wall connecting the vacuum pump 6192 and the membrane structure 611. In this case, the adsorption line 6191 may be formed of a flexible material so as to accommodate vertical height changes between the membrane structure 611 and the base 116.

The vacuum pump 6192 may control a vacuum level of the adsorption line 6191. For example, the vacuum pump 6192 may include a volumetric pump, a molecular pump, an adsorption pump, or a momentum transfer pump. For example, the vacuum pump 6192 may be installed on the base 116, however, the vacuum pump 6192 may be installed on the elastic body 117 or installed outside the base 116.

As described above, although the embodiments have been described with reference to the limited drawings, a person skilled in the art may apply various technical modifications and variations based thereon. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and equivalents of the claims are within the scope of the following claims.

What is claimed is:

1. A wafer chucking system comprising:
a membrane structure comprising a first layer having a first coefficient of thermal expansion (CTE) on which a wafer is mountable, and a second layer having a second CTE different from the first CTE;
a temperature controller configured to heat or cool the membrane structure to thermally deform the membrane structure; and
an adsorber configured to adsorb the wafer on the membrane structure.

2. The wafer chucking system of claim 1, wherein the adsorber comprises:
an adsorption electrode on a lower side of the membrane structure, wherein the adsorption electrode is configured to accumulate a charge when a voltage is applied thereto;
a power supply configured to control a magnitude of the voltage applied to the adsorption electrode.

3. The wafer chucking system of claim 1, wherein
the first layer comprises at least one first aperture, and the second layer comprises at least one second aperture in fluid communication with the at least one first aperture, and the adsorber comprises:
a vacuum line in fluid communication with the at least one first aperture and the at least one second aperture, and wherein the vacuum line is configured to provide a negative pressure to the wafer via the at least one first aperture and the at least one second aperture; and
a vacuum pump configured to adjust a vacuum level in the vacuum line.

4. The wafer chucking system of claim 1, further comprising:
a rigid base; and
an elastic body between the membrane structure and the rigid base,
wherein the elastic body stretches and shrinks in response to a change in a height of each region of the membrane structure relative to the base, and
wherein the elastic body comprises a material having a thermal conductivity lower than an average thermal conductivity of the membrane structure.

5. The wafer chucking system of claim 4, wherein the elastic body comprises a porous, elastic medium.

6. The wafer chucking system of claim 4, further comprising:
at least one sliding guide on the base; and
at least one floating rod on the second layer and configured to slide along the at least one sliding guide in response to deformation of the membrane structure.

7. The wafer chucking system of claim 6, wherein the at least one floating rod comprises a plurality of floating rods, wherein the plurality of floating rods are in contact with the second layer.

8. The wafer chucking system of claim 6, wherein
the at least one floating rod has a diameter greater than a diameter of the at least one sliding guide, and wherein the at least one floating rod comprises an internal space that receives the at least one sliding guide therein, and
the at least one elastic body surrounds a periphery of the at least one sliding guide, wherein the at least one elastic body comprises opposite ends that are supported by the floating rod and the base, respectively.

9. The wafer chucking system of claim 6, wherein
the temperature controller comprises a heat conductor in the at least one sliding guide, and
the heat conductor is configured to heat or cool the second layer through the at least one sliding guide and the at least one floating rod.

10. The wafer chucking system of claim 6, wherein the temperature controller comprises a heat conductor directly connected to the at least one floating rod or the second layer through the at least one sliding guide.

11. The wafer chucking system of claim 6, wherein
the at least one sliding guide has a diameter greater than a diameter of the at least one floating rod, and wherein the at least one sliding guide comprises an internal space for receiving the at least one floating rod therein, and
the at least one elastic body surrounds a periphery of the at least one floating rod, wherein the at least one elastic body comprises opposite ends that are supported by the second layer and the at least one sliding guide, respectively.

12. The wafer chucking system of claim 1, wherein
the membrane structure comprises a plurality of regions, and
the temperature controller comprises a plurality of heat conductors, each of the plurality of heat conductors configured to independently heat or cool a respective one of the plurality of regions.

13. The wafer chucking system of claim 1, wherein
the membrane structure comprises a plurality of regions, and
the membrane structure further comprises an insulating material configured to reduce an amount of heat conducted between the plurality of regions.

14. The wafer chucking system of claim 13, wherein the plurality of regions are arranged in an angular direction around one point of the membrane structure.

15. The wafer chucking system of claim 14, wherein at least a portion of the plurality of regions comprises a plurality of sub-regions radially sectioned from the one point of the membrane structure.

16. The wafer chucking system of claim 13, wherein the plurality of regions are arranged radially from one point of the membrane structure.

17. The wafer chucking system of claim 16, wherein at least a portion of the plurality of regions comprises a plurality of sub-regions sectioned in an angular direction around the one point of the membrane structure.

18. The wafer chucking system of claim 13, wherein the plurality of regions are arranged parallel to each other on the membrane structure.

19. A wafer chucking system comprising:
a membrane structure comprising a plurality of layers, each of the plurality of layers having a respective different coefficient of thermal expansion;
a temperature controller configured to heat or cool the membrane structure to thermally deform the membrane structure; and
an adsorber configured to adsorb the wafer on the membrane structure.

20. A wafer chucking system comprising:
a membrane structure comprising a first layer having a first coefficient of thermal expansion (CTE) on which a wafer is mountable, and a second layer having a second CTE different from the first CTE;
a base;
a plurality of sliding guides attached to one of the base and the second layer;
a plurality of floating rods attached to the other one of the base and the second layer, wherein each of the plurality of floating rods are configured to slide along a respective one of the plurality of sliding guides in response to deformation of the membrane structure;
a plurality of elastic bodies, each elastic body extending around a periphery of a respective one of the plurality of sliding guides, wherein each of the plurality of elastic bodies are configured to expand and contract in response to a change in a height of a respective region of the membrane structure relative to the base;
a temperature controller configured to heat or cool the membrane structure to thermally deform the membrane structure; and
an adsorber configured to adsorb the wafer on the membrane structure.
